(19) United States
(12) Patent Application Publication
(10) Pub. No.: US 2007/0154210 A1
(43) Pub. Date: Jul. 5, 2007

(54) Method and apparatus for dispense pump calibration in a track lithography system

(75) Inventor: Y. Sean Lin, Irvine, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/325,885

(22) Filed: Jan. 4, 2006

(51) Int. Cl. G03D 3/02; B05C 11/00; C23C 16/52

(52) U.S. Cl. 396/632; 396/626; 396/636; 417/12; 118/683; 427/8

(57) ABSTRACT

A method of dispensing a photolithography chemical onto a substrate positioned in a track lithography tool. The method includes determining a target volume of the photolithography chemical for a photolithography process and calculating a pump offset. The pump offset is a second order polynomial function of the target volume. The method also includes providing a dispense value dependent on the pump offset to a dispense pump adapted to deliver the photolithography chemical to the substrate. The method further includes providing a control signal to the dispense pump to initiate delivery of the photolithography chemical to the substrate.

### BACKGROUND OF THE INVENTION

The present invention relates generally to the field of substrate processing equipment. More particularly, the present invention relates to a method and apparatus for providing calibration curves for semiconductor process chemistry. Merely by way of example, the method and apparatus of the present invention are used to control the volume of photoresist dispensed in a photolithography coating system. The method and apparatus can be applied to other processes for semiconductor substrates, for example those used in the formation of integrated circuits.

Modern integrated circuits contain millions of individual elements that are formed by patterning the materials, such as silicon, metal and/or dielectric layers, that make up the integrated circuit to sizes that are small fractions of a micrometer. The technique used throughout the industry for forming such patterns is photolithography.

A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that every substrate processed within the track lithography tool for a particular application has the same “wafer history.” A substrate's wafer history is generally monitored and controlled by process engineers to ensure that all of the device fabrication processing variables that may later affect a device's performance are controlled, so that all substrates in the same batch are always processed the same way.

A component of the “wafer history” is the thickness, uniformity, repeatability, and other characteristics of the photolithography chemistry, which includes, without limitation, photoresist, developer, and solvents. Generally, during photolithography processes, a substrate, for example a semiconductor wafer, is rotated on a spin chuck at predetermined speeds while liquids and gases such as solvents, photoresist (resist), developer, and the like are dispensed onto the surface of the substrate. Typically, the wafer history will depend on the process parameters associated with the photolithography process.

As an example, an inadequate volume of photoresist dispensed during a coating operation will generally impact the uniformity and thickness of coatings formed on the substrate. Additionally, the dispense rate of the photoresist will generally impact film properties, including the lateral spreading of the resist in the plane of the substrate. Therefore, it is desirable to control both the volume and dispense rate of the photoresist applied to the substrate with respect to both the accuracy (e.g., total volume per dispense event) and repeatability (e.g., difference in volume per dispense over a series of dispense events) of the dispense process.

For some photolithography chemical dispense applications, offset adjustments are provided on pumps used to dispense fluids. For example, in some dispense applications, the variation of dispensed fluid volume as a function of target volume is approximated by a linear fit and offset adjustments are calculated in an effort to compensate for discrepancies between desired and actual dispense volumes. However, these linear offset adjustments do not provide the level of control desirable for current and future track lithography tools. Accordingly, further improvements are desired and are continuously sought by process engineers. Therefore, there is a need in the art for improved methods and apparatus for controlling the dispense variables in a photolithography system.

### SUMMARY OF THE INVENTION

According to the present invention techniques related to the field of substrate processing equipment are provided. More particularly, the present invention relates to a method and apparatus for providing calibration curves for semiconductor process chemistry. Merely by way of example, the method and apparatus of the present invention are used to control the volume of photoresist dispensed in a photolithography coating system. The method and apparatus can be applied to other processes for semiconductor substrates, for example those used in the formation of integrated circuits.

According to an embodiment of the present invention, a method of dispensing a photolithography chemical onto a substrate positioned in a track lithography tool is provided. The method includes determining a target volume of the photolithography chemical for a photolithography process and calculating a pump offset. The pump offset is a second order polynomial function of the target volume. The method also includes providing a dispense value dependent on the pump offset to a dispense pump adapted to deliver the photolithography chemical to the substrate. The method further includes providing a control signal to the dispense pump to initiate delivery of the photolithography chemical to the substrate.

According to another embodiment of the present invention, a method of dispensing a photolithography chemical onto a substrate positioned in a track lithography tool is provided. The method includes determining a target flow rate of the photolithography chemical for a photolithography process and calculating a pump offset. The pump offset is a function of the target flow rate. The method also includes providing a control signal incorporating the pump offset to a chemical pump adapted to deliver the photolithography chemical to the substrate. In some embodiments, the pump offset is a linear function of the target flow rate. In other embodiments, the pump offset is a polynomial function of the target flow rate and the polynomial function is of order two or greater.

According to an alternative embodiment of the present invention, an apparatus for dispensing a photolithography chemical onto a surface of a semiconductor substrate in a track lithography tool is provided. The apparatus includes a dispense pump coupled to a supply of the photolithography chemical and a controller coupled to the dispense pump. The controller is adapted to receive a target volume of the photolithography chemical associated with a predetermined photolithography process. According to embodiments of the present invention, the target volume is a function of a pump offset. The controller is also adapted to receive a target flow rate of the photolithography chemical associated with the predetermined photolithography process. The target flow rate is a function of the pump offset. The controller is further adapted to provide a control signal to the dispense pump. The dispense pump operates to dispense a volume of the photolithography chemical within 0.02 ml of the target volume.

According to yet another alternative embodiment of the present invention, a computer program product stored on a computer-readable storage medium for operating a track lithography tool adapted to dispense a photolithography chemical onto a semiconductor substrate is provided. The computer program product includes code for determining a target volume of the photolithography chemical for a photolithography process. The computer program product also includes code for calculating a pump offset. The pump offset is a second order polynomial function of the target volume. The computer program product further includes code for providing a control signal dependent on the pump offset to a chemical pump adapted to deliver the photolithography chemical to the substrate.

Many benefits are achieved by way of the present invention over conventional techniques. For example, embodiments of the present invention reduce the frequency of pump calibration operations in applications for which process variables such as target volume and flow rate are varied. Additionally, embodiments of the present invention reduce the start-up time for photolithography lithography tools and process development. Utilizing embodiments of the present invention, process engineers are able to change process variables more often, resulting in improvements in process optimization. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of an embodiment of a track lithography tool according to an embodiment of the present invention;

FIG. 2 is a simplified schematic illustration of a photolithography chemical dispense apparatus according to an embodiment of the present invention;

FIG. 3 is a three-dimensional plot of dispense error as a function of dispense rate and target volume;

FIGS. 4A-4C are plots of dispense error as a function of target volume measured using an embodiment of the present invention;

FIG. 5 is a simplified flowchart illustrating a method of dispensing a photolithography chemical onto a substrate according to an embodiment of the present invention; and

FIG. 6 is a simplified flowchart illustrating a method of dispensing a photolithography chemical onto a substrate according to another embodiment of the present invention.

### DETAILED DESCRIPTION OF SPECIFIC EMBODIMENTS

According to the present invention techniques related to the field of substrate processing equipment are provided. More particularly, the present invention relates to a method and apparatus for providing calibration curves for semiconductor process chemistry. Merely by way of example, the method and apparatus of the present invention are used to control the volume of photoresist dispensed in a photolithography coating system. The method and apparatus can be applied to other processes for semiconductor substrates, for example those used in the formation of integrated circuits.

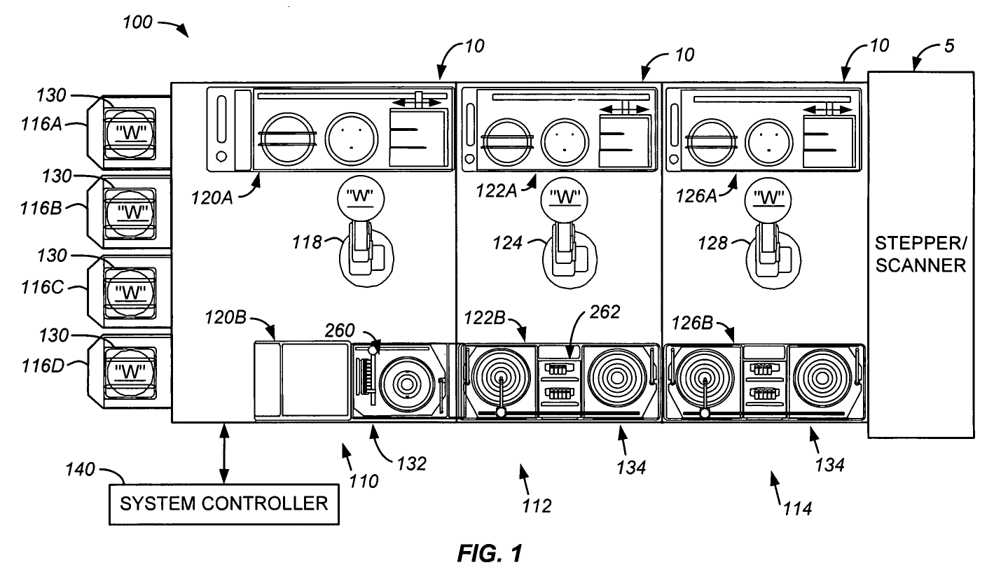

FIG. 1 is a plan view of an embodiment of a track lithography tool 100 in which the embodiments of the present invention may be used. As illustrated in FIG. 1, track lithography tool 100 contains a front end module 110 (sometimes referred to as a factory interface or FI), a central module 112, and a rear module 114 (sometimes referred to as a scanner interface). Front end module 110 generally contains one or more pod assemblies or FOUPS (e.g., items 116A-D), a front end robot 118, and front end processing racks 120A and 120B. The one or more pod assemblies 116A-D are generally adapted to accept one or more cassettes 130 that may contain one or more substrates or wafers, “W,” that are to be processed in track lithography tool 100.

Central module 112 generally contains a first central processing rack 122A, a second central processing rack 122B, and a central robot 124. Rear module 114 generally contains first and second rear processing racks 126A and 126B and a back end robot 128. Front end robot 118 is adapted to access processing modules in front end processing racks 120A, 120B; central robot 124 is adapted to access processing modules in front end processing racks 120A, 120B, first central processing rack 122A, second central processing rack 122B and/or rear processing racks 126A, 126B; and back end robot 128 is adapted to access processing modules in the rear processing racks 126A, 126B and in some cases exchange substrates with a stepper/scanner 5.

The stepper/scanner 5, which may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner/stepper tool 5 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 120A, 120B; 122A, 122B and 126A, 126B contain multiple processing modules in a vertically stacked arrangement. That is, each of the processing racks may contain multiple stacked integrated thermal units 10, multiple stacked coater modules 132, multiple stacked coater/developer modules with shared dispense 134 or other modules that are adapted to perform the various processing steps required of a track photolithography tool. As examples, coater modules 132 may deposit a bottom antireflective coating (BARC); coater/developer modules 134 may be used to deposit and/or develop photoresist layers and integrated thermal units 10 may perform bake and chill operations associated with hardening BARC and/or photoresist layers.

In one embodiment, a system controller 140 is used to control all of the components and processes performed in the cluster tool 100. The controller 140 is generally adapted to communicate with the stepper/scanner 5, monitor and control aspects of the processes performed in the cluster tool 100, and is adapted to control all aspects of the complete substrate processing sequence. In some instances, controller 140 works in conjunction with other controllers, such as a post exposure bake (PEB) controller, to control certain aspects of the processing sequence. The controller 140, which is typically a microprocessor-based controller, is configured to receive inputs from a user and/or various sensors in one of the processing chambers and appropriately control the processing chamber components in accordance with the various inputs and software instructions retained in the controller's memory. The controller 140 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 140 determines which tasks are performable in the processing chamber(s). Preferably, the program is software readable by the controller 140 and includes instructions to monitor and control the process based on defined rules and input data.

It is to be understood that embodiments of the invention are not limited to use with a track lithography tool such as that depicted in FIG. 1. Instead, embodiments of the invention may be used in any track lithography tool including the many different tool configurations described in U.S. application Ser. No. 11/112,281, entitled “Cluster Tool Architecture for Processing a Substrate” filed on Apr. 22, 2005, which is hereby incorporated by reference for all purposes and including configurations not described in the above referenced application.

Generally, track lithography tools are used to dispense precise amounts of expensive lithography chemicals onto substrates to form thin, uniform coatings. For modern lithography processes, the volumes of chemicals, such as photoresist, dispensed per event are small, for example, ranging from about 0.5 ml to about 5.0 ml. The volume of chemical dispensed, the flow rate during the dispense operation, among other variables, are controlled during the process of dispensing the lithography chemicals, for example, photoresist. Preferably, control of the dispense operations in a track lithography tool provide actual dispensed volumes with an accuracy of ±0.02 milliliters (ml) and repeatability from dispense event to dispense event of 3σ<0.02 ml.

A wide variety of photolithography chemicals are utilized in track lithography tools according to embodiments of the present invention. For example, photoresist, bottom anti-reflective coating (BARC), top anti-reflective coating (TARC), top coat (TC), Safier, and the like are dispensed onto the substrate. In some embodiments, after the selected chemical is dispensed, the substrate is spun to create a uniform thin coat on an upper surface of the substrate. Generally, to provide the levels of uniformity desired of many photolithography processes, dispense events start with a solid column of chemical. The flow rate is generally set at a predetermined rate as appropriate to a particular chemical deliver process. For example, the flow rate of the fluids is selected to be greater than a first rate in order to prevent the fluids from drying out prior to dispense. At the same time, the flow rate is selected to be less than a second rate in order to maintain the impact of the fluid striking the substrate below a threshold value.

As the dispense event is terminated, the fluid is typically drawn back into the dispense line, sometimes referred to as a suck-back process utilizing a suck-back valve. In some track lithography tools, the fluid is brought back into the dispense line about 1-2 mm from the end of the dispense nozzle, forming a reverse meniscus. This suck-back process prevents the lithography chemicals from dripping onto the substrate and prevents the chemicals from drying out inside the nozzle.

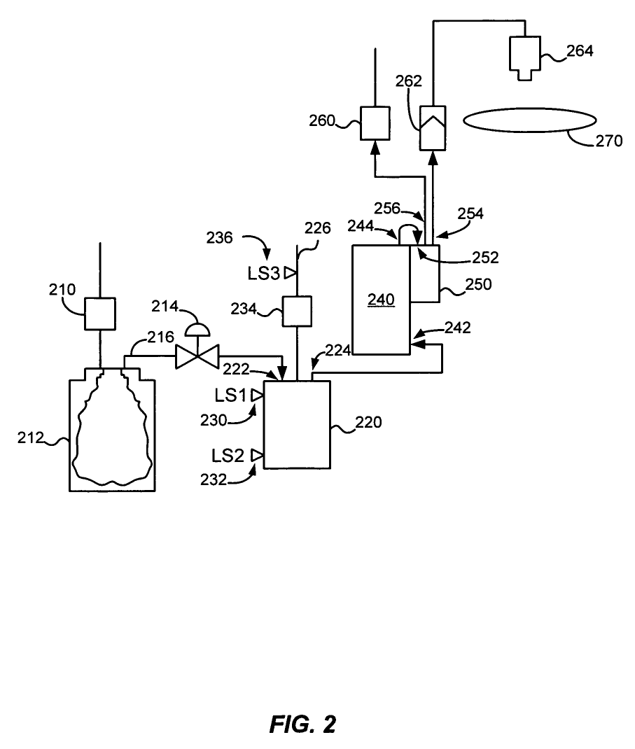

FIG. 2 is a simplified schematic illustration of a photolithography chemical dispense apparatus according to an embodiment of the present invention. A pressure valve 210 is coupled to a source bottle 212 containing the photolithography chemical to be dispensed onto the substrate surface. in an embodiment, the source bottle is a NOWPak® container available from ATMI, Inc., Danbury, Conn. The source bottle is coupled to a flow control valve 214 and adapted to regulate the flow of the photolithography chemical in fluid line 216. Buffer vessel 220 is illustrated in FIG. 2 and includes an input port 222, an output port 224, and a vent port 226. The input port 222 of the buffer vessel 220 is coupled to the fluid line 216. As illustrated in FIG. 2, the buffer vessel includes a number of level sensors, for example, level sensor LS1 (230) and level sensor LS2 (232). As described more fully below, the level sensors are utilized to regulate the volume of photolithography chemical present in the buffer vessel 220.

The vent port 226 of the buffer vessel is coupled to a vent valve 234 and a level sensor LS3 (236). Level sensor LS3 serves to monitor the level of fluid passing through the vent valve 234. The output port 224 of the buffer vessel is coupled to input port 242 of dispense pump 240. As illustrated in FIG. 2, a filter 250 is integrated with the dispense pump 240 and the output port 244 of the dispense pump is coupled to an input port 252 of the filter 250. A vent port 256 and an output port 254 are provided on the filter 250 and, as illustrated in FIG. 2, a vent valve 260 is coupled to the vent port 256. A shut off/suck-back valve 262 is coupled to the fluid line running from the output port 254 of the filter. From valve 262, the photolithography chemical is delivered to substrate 270 through dispense nozzle 264. As will be evident to one of skill in the art, apparatus adapted to chuck and spin the substrate are not illustrated for purposes of clarity. Furthermore, additional dispense systems adapted to provide photolithography chemicals, e.g., multi-nozzle systems, are not illustrated for purposes of clarity.

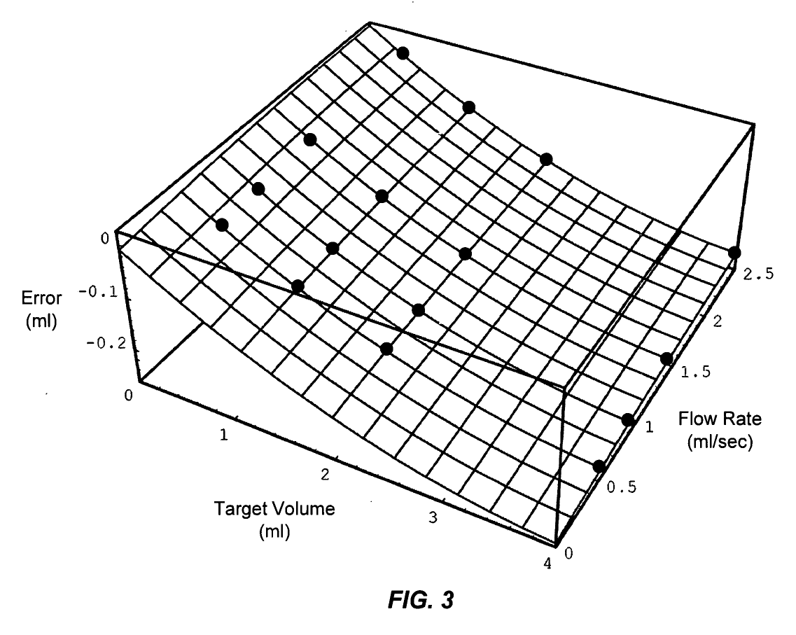

FIG. 3 is a plot of dispense error (in milliliters) as a function of dispense target volume (in milliliters) and dispense rate (in milliliters per second). To collect the data shown in FIG. 3, the dispense system was manually adjusted at a baseline target dispense volume of 1.0 ml at a flow rate of 1.0 ml/sec. In some adjustment procedures, the manual adjustment was qualitative, not quantitative. A goal of the manual adjustment process was to produce a smooth dispense operation, free from spitting and splashing, that was drip-free and repeatable. Some of the parameters adjusted during the manual adjustment process included the timing of the shut-off and suck-back valves, as well as the speed controllers attached to the shut-off and suck-back valves. A series of dispense studies were performed for a series of target volumes ranging from 0.5 ml to 4.0 ml. As illustrated by the data points in FIG. 3, data was collected for target volumes of 0.5 ml, 1.0 ml, 2.0 ml, and 4.0 ml. For each of these target volumes, a series of flow rates (0.5 ml/sec, 1.0 ml/sec, 1.5 ml/sec, and 2.5 ml/sec) was utilized. Referring to FIG. 3, the dispense volume error observed in these studies was consistently less than zero, that is, the actual volume dispensed was less than the target volume. For purposes of clarity, the absolute value of the dispense error is discussed below.

As illustrated in FIG. 3, the dispense volume error varied from about 0.03 ml for a target rate of 0.5 ml and a flow rate of 2.5 ml/sec to about 0.25 ml for a target rate of 4.0 ml and a flow rate of 0.5 ml/sec. The grid illustrated in FIG. 3 is merely for illustrative purposes. For all target volumes, the dispense volume error decreases as the flow rate increases. Moreover, the slope of the dispense error as a function of target volume is greater than the slope of the dispense error as a function of the flow rate. Thus, the sensitivity of the dispense volume error to the target volume is greater than the sensitivity to flow rate.

In the dispense studies illustrated in FIG. 3, a Koganei CT6 dispense pump, available from Koganei Corporation of Tokyo, Japan was used. However, embodiments of the present invention are not limited to a particular chemical pump. Merely by way of example, dispense pumps such as the Mykrolis IntelliGen®2 and Intelligen®3, available from the Mykrolis Corporation, Billerica, Mass.; the IDI BP-5X, available from the IDI-Cybor Corp. of Carrollton, Tex.; the Iwaki PDS, available from the Iwaki America Inc., Holliston, Mass.; and the like are included within the scope of the present invention. Moreover, the functional relationships illustrated in FIG. 3 are not intended to limit the scope of the present invention. One of ordinary skill in the art would recognize many variations, modifications, and alternatives.

As will be evident to one of skill in the art, a dispense volume error in which less photoresist than desired is delivered, may result in a film of photoresist, for example, that does not cover the entire substrate. Alternatively, providing an excess volume of photoresist results in waste, which is a manufacturing concern when using photoresists costing as much as $1,000 or more per gallon. Accordingly, embodiments of the present invention reduce the dispense volume errors associated with photolithography chemical dispense systems, thereby improving process uniformity and repeatability.

In some track lithography tools, the dispense volume and flow rate are selected for a particular process. Because of the dispense volume errors illustrated in FIG. 3, the dispense pump is adjusted in an iterative manner to achieve the particular dispense volume and flow rate settings associated with a particular process. For example, if a dispense volume of 1.0 ml is desired and the actual dispense volume is 0.9 ml, an error of −0.1 ml, an offset calibration process is performed, in which the target dispense volume is raised to 1.1 ml (an initial offset of ±0.1 ml). After the initial offset is selected, the actual dispense volume, for example, may be 0.99 ml rather than the desired 1.0 ml. According, the offset is raised again, in an iterative manner, until the offset, in combination with the target value, provides an actual dispense volume of 1.0 ml plus or minus the acceptable process or measurement error.

Although this method is satisfactory for some applications with fixed dispense volumes and flow rates, applications in which the dispense volumes and flow rates are variable present problems. Generally, to modify the target volume and/or the flow rate, as well as other chemical delivery parameters, the iterative calibration process described above is repeated, consuming time and resources. As a result, for these modifications, calibration of the target volume offset is added to the process recipe, increasing process time and utilizing resources.

Calibration is not limited to applications with variable target volumes and flow rates. In applications for which the target volume and flow rate are initially fixed at a first set of values and subsequently modified to a second set of values, the recalibration process is generally performed. Thus, as in variable parameter processes, iterative calibration processes are generally utilized, increasing the time and resources needed to perform a particular chemical delivery process.

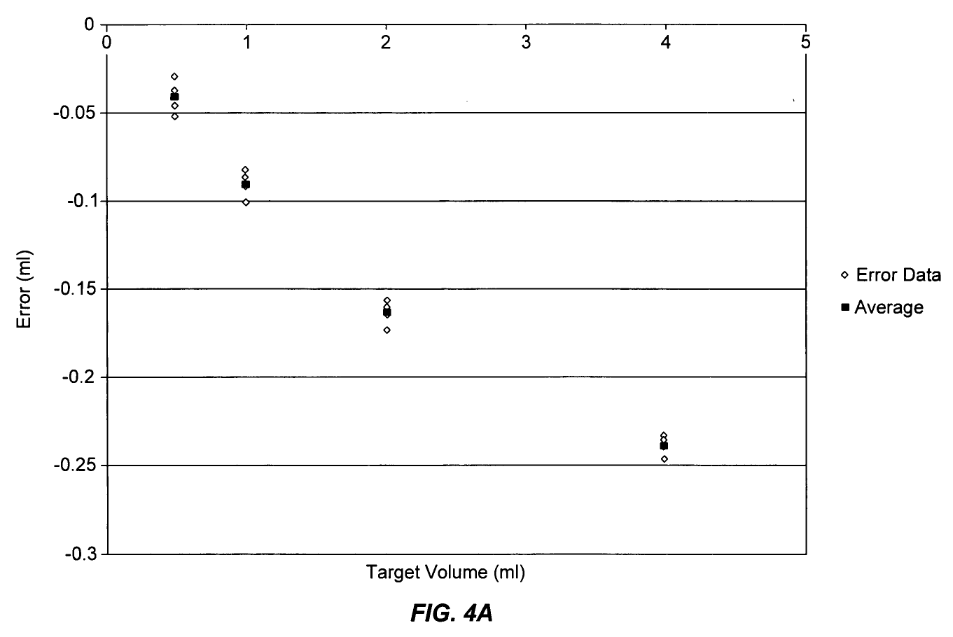

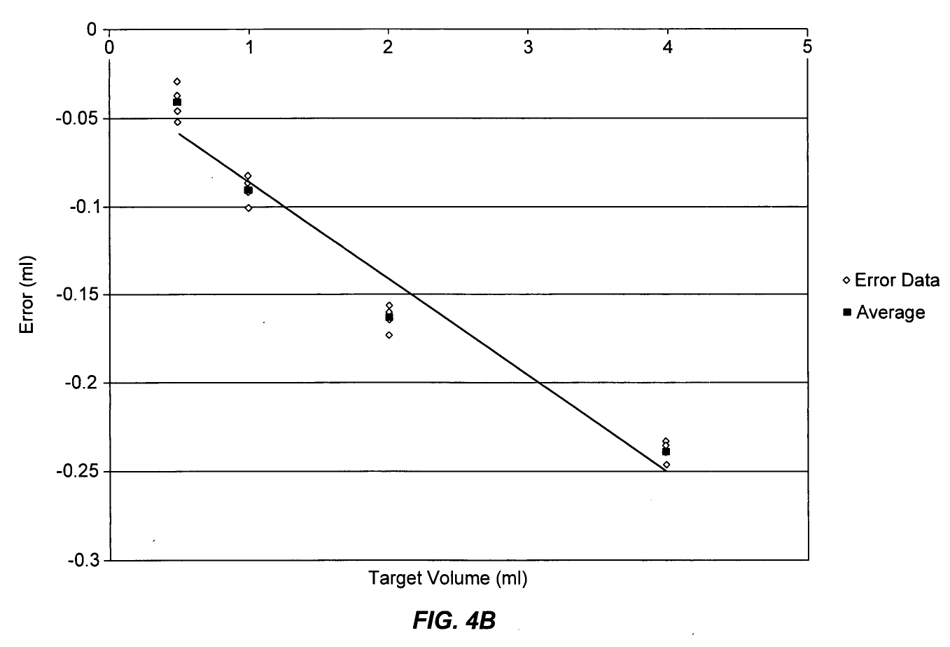

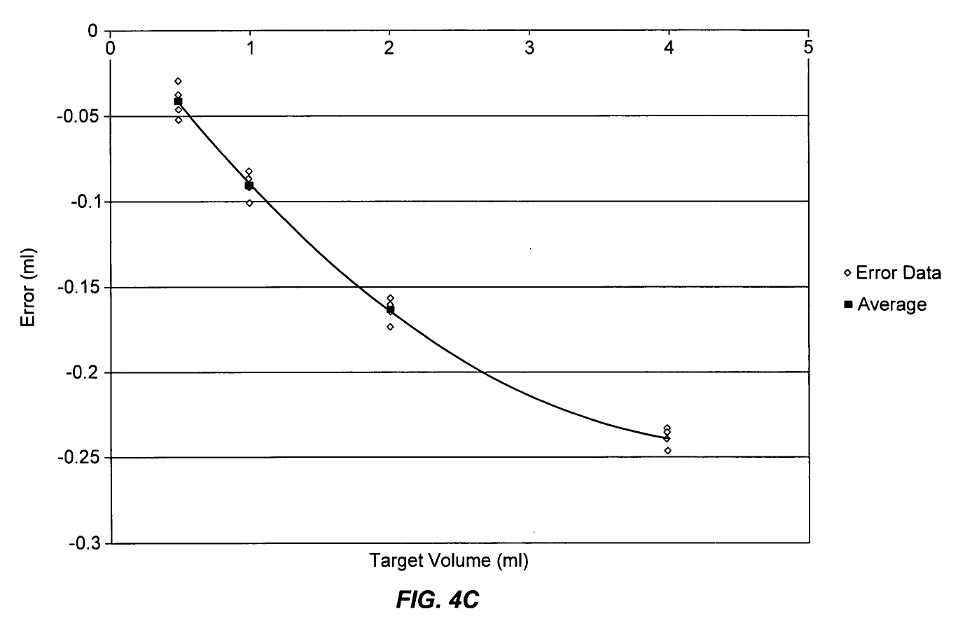

FIGS. 4A to 4C are plots of dispense error as a function of target volume measured using an embodiment of the present invention. FIG. 4A shows the dispense volume error as a function of target volume. At each target volume level, data is presented for several dispense events performed using a range of dispense rates or flow rates. Additionally, the dispense volume error for the various flow rates is averaged and presented as the solid symbol in the graph and in the legend. As shown in FIG. 4A, embodiments of the present invention determine a target volume of the photolithography chemical dispensed during a photolithography process. For example, a target volume of 1.0 ml is selected for a particular process. In some embodiments, the target volume of 1.0 ml is selected to provide a uniform thin film coating covering an entire substrate. As will be evident to one of skill in the art, the viscosity of the chemical, any solvents pre-dispensed on the substrate, the substrate spin rate, and the like, will impact this choice of a target volume.

Embodiments of the present invention also calculate a pump offset, which is a function of the target volume, the flow rate, and the like. In the example illustrated in FIG. 4A, for target volume of 0.5 ml, the pump offset is approximately 0.04 ml. For a target volume of 4 ml, the pump offset is approximately 0.24 ml. A control signal is generated and delivered to a chemical pump adapted to deliver the photolithography chemical to the substrate. As described more fully below, a functional relationship between the dispense error, the target volume, the flow rate, and/or other variables is defined utilizing embodiments of the present invention.

Accordingly, embodiments of the present invention provide a method of dispensing resist in a track lithography tool in which recalibration of the target volume offset is reduced or eliminated. FIG. 4B presents the data shown in FIG. 4A along with a linear curve fit to the data. The linear curve fit provides an estimate of the dispense error as a function of target volume, although the estimates at 0.5 ml volume and the 2.0 ml volumes differ significantly from the actual dispense error data. For example, at a target volume of 2.0 ml, all data points measured over the entire range of flow rates are less than the estimate provided by the linear curve fit. For this target volume, correcting the target volume offset in accordance with the linear estimate would result in an actual target volume less than desired. For comparison, the error is overestimated at a target volume of 0.5 ml, resulting in a condition in which the actual target volume exceeds the desired volume.

FIG. 4C presents the data shown in FIG. 4A along with a second-order polynomial curve fit (a quadratic polynomial). Comparing FIGS. 4B and 4C, the correlation between the dispense error and the estimate provided by the polynomial curve fit is significantly better than the linear curve fit. Referring once again to the target volumes of 0.5 ml and 2.0 ml, the estimate provided by the curve fit more closely approximates the actual data collected. Utilizing the estimate of dispense error provided by the polynomial curve fit illustrated in FIG. 4C, the system operator is enabled to accurately and repeatably control the volume of fluid delivered to the substrate over a range of target volumes and flow rates. Accordingly, the time intensive process of recalibrating the dispense system in response to changes in delivery volume or flow rate set points is reduced or eliminated.

Referring once again to FIGS. 3 and 4C, embodiments of the present invention provide multi-dimensional polynomial curve fits that estimate the dispense volume error as a function of dispense parameters, such as target volume or flow rate among other parameters. Using the polynomial curve fit illustrated in FIG. 4C, the variation in dispense error as a function of flow rate, although a fraction of the dispense error as a function of target volume, is not accounted for by a curve fit dependent only on the target rate. Thus, embodiments of the present invention provide offset adjustments as functions of both target volume and flow rate.

According to some embodiments of the present invention, the offset adjustment calculated as described above, is utilized to modify a pump volume value. In other embodiments, the offset adjustment is utilized to generate a control signal that is a function of the offset adjustment. Utilizing embodiments of the present invention, a system operator is provided with additional control over the volume of fluid delivered to the substrate under a variety of dispense parameters. In a particular embodiment, pump software utilizes a desired target volume to calculate a pump offset. In some embodiments, the software controls the operation of the photolithography chemical pump. In other embodiments, a dispense value dependent on the pump offset is downloaded to a pump controller, which is then activated after the provision of a control signal, for example, a trigger signal.

In addition to the process parameters discussed above, additional embodiments of the present invention include additional process parameters to estimate target volume errors. Referring to FIG. 2, additional process parameters include the head pressure between the buffer vessel 220 and the pump 240 as well as the head pressure between the pump 240 and the dispense nozzle 264. According to embodiments of the present invention, a multi-dimensional model is created based on target volume error measurements made using dispense systems. In a particular embodiment, a functional relationship is established between target volume errors and the target volume, the flow rate, the bottle-pump head pressure, the pump-nozzle head pressure, and the like. One of ordinary skill in the art would recognize many variations, modifications, and alternatives. In some embodiments, the pump controller is provided with a dispense value that is a function of the multi-dimensional model. A control signal is then provided to the dispense pump to initiate delivery of the photolithography chemical to a substrate. In other embodiments, a control signal dependent on the multi-dimensional model is provide to a pump controller. In these embodiments, the control signal includes both data and dispense initiation information.

According to a specific embodiment of the present invention, a multi-dimensional model is created based on data collection procedures as described above. A database is generated based on this multi-dimensional model. In a particular embodiment, the database is represented by a lookup table stored in a memory. For example, during operation of the track lithography tool, a pump controller receives dispense instructions from a system controller (see reference number 140 in FIG. 1). The pump controller utilizes the dispense instructions (including, e.g. a dispense target volume and a flow rate) and data related to the dispense system fluid levels, head pressures, and the like in accessing the lookup table stored in memory. In some embodiments, interpolation of values is utilized to select variable values present in the lookup table. Utilizing the dispense instructions and other data, a dispense offset is generated from dispense error values stored in the lookup table. The dispense offset is utilized during programming of the dispense controller to improve the accuracy and repeatability of the dispense process. One of ordinary skill in the art would recognize many variations, modifications, and alternatives.

In an alternative embodiment, a multi-dimensional model is created based on data collection procedures as described above. Multi-dimensional polynomial fits are generated based on the multi-dimensional model and polynomial coefficients associated with the multi-dimensional polynomial fits are stored in a memory. Pump controller software is adapted to access the polynomial coefficients and calculate a pump offset as a function of the desired pump variables, including, but not limited to, target volume and flow rate. In these embodiments, the pump controller software is adapted to initiate and control the dispense operations based on the pump offset among other parameters and variables.

Embodiments of the present invention provide features including multiple step dispense operations with rate changes for each step and variable rate dispense with rate changes occurring continuously during the dispense process. Thus, in an exemplary embodiment, the overall dispense process for a substrate is divided into a number of sub-steps, each sub-step characterized by a dispense volume and flow rate. The flow rate varies from step to step, adjusting the dispense volume offset as a function of the changes in the flow rate. Of course, as will be evident to one of skill in the art, the target volume may be varied from sub-step to sub-step using embodiments of the present invention. One of ordinary skill in the art would recognize many variations, modifications, and alternatives.

In another exemplary embodiment, a predetermined dispense volume is provided by calculating dispense volume offsets as a function of the target volume and the flow rates, which are changing during the dispense step. In a manner similar to the multi-step dispense process discussed above, the dispense volume offset is adjusted continuously as the rate is varied during the dispense operation.

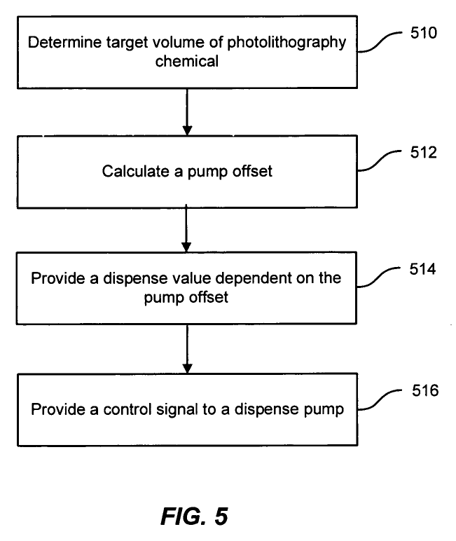

FIG. 5 is a simplified flowchart illustrating a method of dispensing a photolithography chemical onto a substrate according to an embodiment of the present invention. In some embodiments, the dispense pump is calibrated at a predetermined target dispense volume and flow rate. For example, the dispense pump may be calibrated using a manual calibration method as described above at a target dispense volume of 1.0 ml and a flow rate of 1.0 ml/sec. According to the method 500, a target volume of a photolithography chemical is determined (510) and a pump offset is calculated (512). As described above, the pump offset is determined in embodiments of the present invention by using data collected from a series of dispense operations performed using the dispense system.

In an embodiment, the pump offset is a second order polynomial function of the target volume. In another embodiment, the pump offset is a second order polynomial function of the target volume and the flow rate. A dispense value is provided (514) that is dependent on the pump offset. In some embodiments, the dispense value is a function of the pump offset. In other embodiments, an initial dispense value is modified by the pump offset to obtain a second dispense value. One of ordinary skill in the art would recognize many variations, modifications, and alternatives.

A control signal is provided to a dispense pump (516) to initiate delivery of the photolithography chemical to the substrate. In a particular embodiment, the dispense pump is adapted to deliver a trigger signal that initiates the dispense operation of the photolithography chemical, providing a volume of chemical substantially equal to the dispense value. Embodiments of the present invention utilize photolithography chemicals including, without limitation, photoresists, developers, and solvents. In a particular embodiment, the pump offset is a third order or greater polynomial function of the target volume.

Utilizing the pump offset determined as described in relation to FIG. 5, modifications of the target dispense volume, flow rate, and the like are compensated for prior to dispense. For example, if the desired target volume is modified from a previously utilized value, the pump offset is determined for the new target volume and the control signal provided to the dispense pump is modified accordingly. Thus, embodiments of the present invention provide for accurate and repeatable dispense operations without performing recalibration of the dispense system for each change in pump variables.

The above sequence of steps provides a method for dispensing a photolithography chemical onto a substrate positioned in a track lithography tool according to an embodiment of the present invention. As shown, the method uses a combination of steps including a way of calculating a pump offset as a function of dispense variables, such as target volume, according to an embodiment of the present invention. Other sequences of steps may also be performed according to alternative embodiments.

Moreover, the individual steps illustrated by this figure may include multiple sub-steps that may be performed in various sequences as appropriate to the individual step. Furthermore, other alternatives can also be provided where steps are added, one or more steps are removed, or one or more steps are provided in a different sequence without departing from the scope of the claims herein. One of ordinary skill in the art would recognize many variations, modifications, and alternatives.

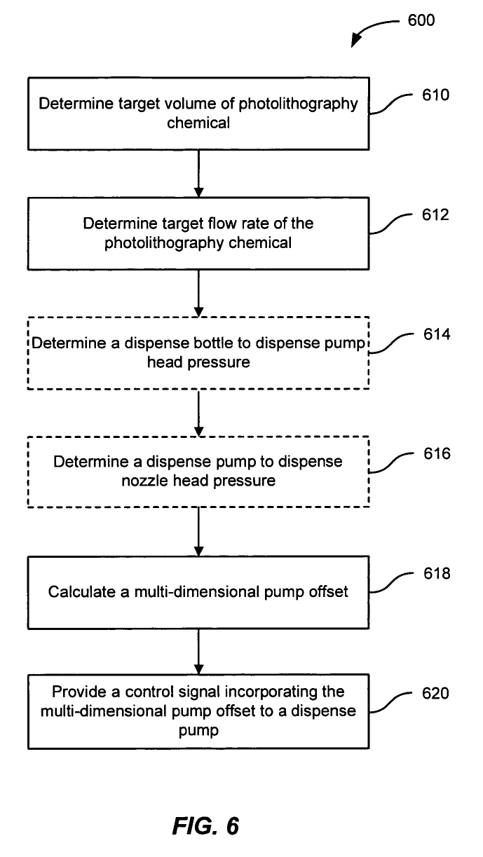

FIG. 6 is a simplified flowchart illustrating a method of dispensing a photolithography chemical onto a substrate according to another embodiment of the present invention. A target volume of a photolithography chemical is determined (610) and a target flow rate of the photolithography chemical is determined (612) as part of this method (600). A series of optional steps follow, including determining a dispense bottle to dispense pump head pressure (614) and a dispense pump to dispense nozzle head pressure (616). Depending on the embodiment, the number of variables selected for determination will vary, depending on the accuracy, repeatability, and/or other factors of interest to the system operator. A multi-dimensional pump offset is calculated (618) as a function of at least one of the target volume, the target flow rate, the dispense bottle to dispense pump head pressure, and/or the dispense pump to dispense nozzle head pressure. In an embodiment, the pump offset is a second order polynomial function of the selected parameters. A control signal is provided to a dispense pump (620). In a specific embodiment, the control signal incorporates the pump offset and thereby compensates for the dispense volume error described above. Merely by way of example, in an embodiment, the control signal comprises a dispense value calculated as a function of the dispense offset and a trigger signal adapted to initiate the dispensing of the dispense value. The control signal is downloaded to a pump controller in some embodiments after the dispense value is determined. In other embodiments, an initial dispense value and the pump offset are downloaded to the pump controller and a second dispense value is calculated as a function of the dispense offset once the values are resident in the pump controller. One of ordinary skill in the art would recognize many variations, modifications, and alternatives.

The above sequence of steps provides a method for dispensing a photolithography chemical onto a substrate positioned in a track lithography tool according to an embodiment of the present invention. As shown, the method uses a combination of steps including a way of calculating a pump offset as a function of dispense variables according to an embodiment of the present invention. Other sequences of steps may also be performed according to alternative embodiments. For example, alternative embodiments of the present invention may perform the steps outlined above in a different order. For instance, the order in which the dispense parameters are determined may be varied.

Moreover, the individual steps illustrated by this figure may include multiple sub-steps that may be performed in various sequences as appropriate to the individual step. Furthermore, other alternatives can also be provided where steps are added, one or more steps are removed, or one or more steps are provided in a different sequence without departing from the scope of the claims herein. One of ordinary skill in the art would recognize many variations, modifications, and alternatives.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A method of dispensing a photolithography chemical onto a substrate positioned in a track lithography tool, the method comprising:
determining a target volume of the photolithography chemical for a photolithography process;
calculating a pump offset, wherein the pump offset is a second order polynomial function of the target volume;
providing a dispense value dependent on the pump offset to a dispense pump adapted to deliver the photolithography chemical to the substrate; and
providing a control signal to the dispense pump to initiate delivery of the photolithography chemical to the substrate.

2. The method of claim 1 wherein the photolithography chemical is at least one of a photoresist, a developer, or a solvent.

3. The method of claim 1 wherein the photolithography chemical is at least one of a BARC, TARC, TC, ARC, SOD, SOP, SOG, or a Shrink.

4. The method of claim 1 wherein the pump offset is a third order or greater polynomial function of the target volume.

5. The method of claim 1 wherein the dispense pump is adapted to deliver a volume of the photolithography chemical within 0.02 ml of the target volume.

6. The method of claim 1 further comprising:
determining a target flow rate of the photolithography chemical for the photolithography process; and
calculating an updated pump offset, wherein:
the updated pump offset is a second order polynomial function of the target volume and the target flow rate, and
the dispense value is dependent on the updated pump offset.

7. The method of claim 6 further comprising:
determining a bottle to dispense pump head pressure;
determining a dispense pump to nozzle head pressure; and
calculating a further updated pump offset, wherein:
the further updated pump offset is a second order polynomial function of the target volume, the target flow rate, the bottle to dispense pump head pressure, and the dispense pump to nozzle head pressure, and
the dispense value is dependent on the updated pump offset.

8. A method of dispensing a photolithography chemical onto a substrate positioned in a track lithography tool, the method comprising:
determining a target flow rate of the photolithography chemical for a photolithography process;
calculating a pump offset, wherein the pump offset is a function of the target flow rate; and
providing a control signal incorporating the pump offset to a chemical pump adapted to deliver the photolithography chemical to the substrate.

9. The method of claim 8 wherein the pump offset is a linear function of the target flow rate.

10. The method of claim 9 wherein the pump offset is a polynomial function of the target flow rate and the polynomial function is of order two or greater.

11. The method of claim 8 further comprising:
determining a target volume of the photolithography chemical for a photolithography process;
calculating a multi-dimensional pump offset, wherein the multi-dimensional pump offset is a function of the target flow rate and the target volume and wherein the control signal incorporates the multi-dimensional pump offset.

12. The method of claim 11 wherein the multi-dimensional pump offset is a polynomial function of order two or greater.

13. An apparatus for dispensing a photolithography chemical onto a surface of a semiconductor substrate in a track lithography tool, the apparatus comprising:
a dispense pump coupled to a supply of the photolithography chemical;
a controller coupled to the dispense pump, the controller adapted to:
receive a target volume of the photolithography chemical associated with a predetermined photolithography process, wherein the target volume is a function of a pump offset;
receive a target flow rate of the photolithography chemical associated with the predetermined photolithography process, wherein the target flow rate is a function of the pump offset; and
provide a control signal to the dispense pump, wherein the dispense pump operates to dispense a volume of the photolithography chemical within ±0.02 ml of the target volume.

14. The apparatus of claim 13 wherein the pump offset value is a quadratic function of the target volume and the target flow rate.

15. The apparatus of claim 13 wherein the controller is further adapted to receive a system head pressure associated with dispensing the photolithography chemical and at least one of the target volume or the target flow rate are a function of the system head pressure.

16. The apparatus of claim 15 wherein the system head pressure is at least one of a buffer vessel to dispense pump head pressure or a dispense pump to dispense nozzle head pressure.

17. A computer program product stored on a computer-readable storage medium for operating a track lithography tool adapted to dispense a photolithography chemical onto a semiconductor substrate, the computer program product comprising:
code for determining a target volume of the photolithography chemical for a photolithography process;
code for calculating a pump offset, wherein the pump offset is a second order polynomial function of the target volume; and
code for providing a control signal dependent on the pump offset to a chemical pump adapted to deliver the photolithography chemical to the substrate.

18. The computer program product of claim 17 further comprising:
code for determining a target flow rate of the photolithography chemical for the photolithography process;
code for calculating a multi-dimensional pump offset, wherein the multi-dimensional pump offset is a second order or greater polynomial function of the target volume and one of a linear or second order or greater polynomial function of the target flow rate; and
code for providing a control signal dependent on the multi-dimensional pump offset to the chemical pump.

19. The computer program product of claim 17 wherein the photolithography chemical is at least one of a photoresist, a developer, or a solvent.

20. The computer program product of claim 17 wherein the chemical pump is adapted to deliver the photolithography chemical to the substrate within ±0.02 ml of the target volume.
